(19) United States
(12) Patent Application Publication
(10) Pub. No.: US 2019/0043692 A1
(43) Pub. Date: Feb. 7, 2019

(54) CHARGED PARTICLE BEAM WRITING APPARATUS, CHARGED PARTICLE BEAM WRITING METHOD, AND PATTERN FORMING METHOD

(71) Applicant: NuFlare Technology, Inc., Yokohama-shi (JP)

(72) Inventor: Rumi Ito, Yokohama-shi (JP)

(73) Assignee: NuFlare Technology, Inc., Yokohama-shi (JP)

(21) Appl. No.: 16/050,080

(22) Filed: Jul. 31, 2018

(30) Foreign Application Priority Data
Aug. 1, 2017 (JP) 2017-149318

(51) Int. Cl. H01J 37/302

(52) U.S. Cl. CPC H01J 37/302; H01J 2237/31798; H01J 2237/153

(57) ABSTRACT

In one embodiment, a charged particle beam writing apparatus includes an estimator calculating an estimated value of a process parameter of a processing device at a scheduled timing at which a substrate as an object of pattern correction is processed in the processing device from a history of the process parameter of the processing device which performs a process after pattern writing, a predictor predicting dimension distribution of a pattern formed on the substrate by the processing device performing the process with the estimated value, a corrector correcting a design dimension based on the predicted dimension distribution, and a writer irradiating the substrate with a charged particle beam and writing the pattern based on the dimension corrected by the corrector.

### CROSS REFERENCE TO RELATED APPLICATION

This application is based upon and claims benefit of priority from the Japanese Patent Application No. 2017-149318, filed on Aug. 1, 2017, the entire contents of which are incorporated herein by reference.

### FIELD

The present invention relates to a charged particle beam writing apparatus, a charged particle beam writing method, and a pattern forming method.

### BACKGROUND

With an increase in the packing density of LSIs, the required linewidths of circuits included in semiconductor devices become finer year by year. To form a desired circuit pattern on a semiconductor device, a method is employed in which a pattern of a photomask is transferred to a wafer in a reduced manner by using a reduced-projection exposure apparatus. A high-precision original pattern is written by using an electron-beam writing apparatus, in which a so-called electron-beam lithography technique is employed.

For example, a photomask is made by processing a light shielding film such as a chromium film, which is formed on a quartz substrate. The processing of the light shielding film is performed as below. First, a resist is applied onto the light shielding film and a desired pattern is written on the resist by an electron beam writing apparatus. In processes after the writing process, a resist pattern with a desired shape is formed through a development process. Subsequently, the light shielding film is processed by dry etching or wet etching with the resist pattern as a mask.

In the development, etching, and so on after the writing, while taking the kinds of the substrate and resist, the film thickness of the resist, the kind of the written pattern, and the like into account, process parameters such as the bias power, pressure, gas flow rate, and the like of the etcher are optimized to perform the processes. However, there has been a problem that the process parameters vary as time elapses and the dimensions of the pattern after the processing vary. The parameter setting resolution of the etcher has been coarse and it has been failed to cope with the variation in the process parameters accompanied by the lapse of time.

### BRIEF DESCRIPTION OF THE DRAWINGS

FIG. 1 is a schematic diagram of an electron beam writing apparatus according to an embodiment of the present invention.

FIG. 2 is a perspective view of a first shaping aperture and a second shaping aperture.

FIG. 3 is a flow chart for describing a method of correcting a pattern according to the embodiment.

FIG. 4 is a flow chart for describing a method of determining variation in process parameter according to the embodiment.

FIG. 5 is a graph that illustrates an example of a relation between a position on a substrate and a dimension.

FIGS. 6A to 6C are graphs that illustrate relations between process parameters and coefficients of approximate expressions of dimension distributions.

FIG. 7A is a graph that illustrates an example of a history of a process parameter and FIG. 7B is a graph that illustrates an estimated value of the process parameter.

FIG. 8 is a graph that illustrates an example of a relation between a position on a substrate and a dimensional estimated value.

### DETAILED DESCRIPTION

In one embodiment, a charged particle beam writing apparatus includes an estimator calculating an estimated value of a process parameter of a processing device at a scheduled timing at which a substrate as an object of pattern correction is processed in the processing device from a history of the process parameter of the processing device which performs a process after pattern writing, a predictor predicting dimension distribution of a pattern formed on the substrate by the processing device performing the process with the estimated value, a corrector correcting a design dimension based on the predicted dimension distribution, and a writer irradiating the substrate with a charged particle beam and writing the pattern based on the dimension corrected by the corrector.

Hereinafter, an embodiment of the present invention will be described based on the drawings. In the embodiment, as an example of a charged particle beam, a configuration using an electron beam will be described. However, the charged particle beam is not limited to an electron beam, and may be an ion beam or the like.

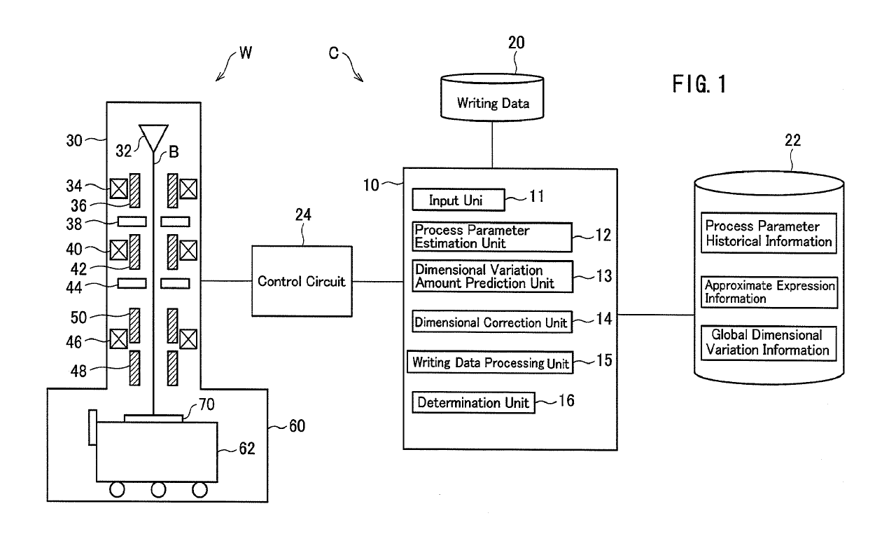

FIG. 1 is a schematic diagram of an electron beam writing apparatus according to an embodiment of the present invention. The electron beam writing apparatus illustrated in FIG. 1 is a variable shaping type writing apparatus that includes a control unit C and a writing unit W.

The writing unit W includes a column 30 and a writing chamber 60. In the column 30, an electron gun 32, an illumination lens 34, a blanker 36, a first shaping aperture 38, a projection lens 40, a shaping deflector 42, a second shaping aperture 44, an objective lens 46, a main deflector 48, and a sub-deflector 50 are arranged.

In the writing chamber 60, an XY stage 62 is arranged. On the XY stage 62, a substrate 70 as an object of writing is placed. The substrate 70 is a mask for exposure to light in manufacture of a semiconductor device or is a semiconductor substrate (silicon wafer) from which a semiconductor device is manufactured, for example. Further, the substrate 70 may be a mask blank where a resist is applied and nothing is written yet.

When an electron beam B emitted from the electron gun 32 (an emission unit) arranged in the column 30 passes through the blanker (a blanking deflector), the blanker 36 switches whether the substrate 70 is irradiated with the electron beam.

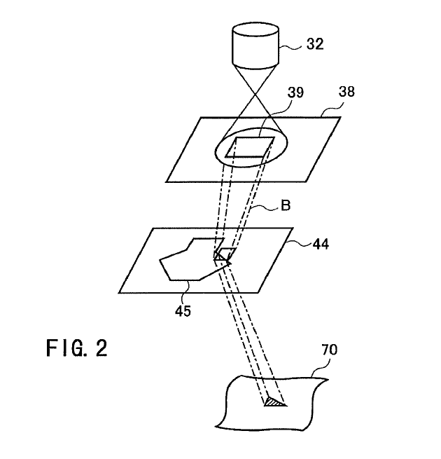

The illumination lens 34 causes the first shaping aperture 38 that includes a rectangular opening 39 (see FIG. 2) to be irradiated with the electron beam B. By passing through the opening 39 of the first shaping aperture 38, the electron beam B is shaped into a rectangle.

The electron beam B that passes through the first shaping aperture 38 to be a first aperture image is projected through the projection lens 40 onto the second shaping aperture 44 that includes an opening 45 (see FIG. 2). At the time, the first aperture image projected onto the second shaping aperture 44 undergoes deflection control by the deflector 42 and the shape and dimensions of the electron beam that passes through the opening 45 can be varied (variable shaping can be performed).

The electron beam B that passes through the opening 45 of the second shaping aperture 44 to be a second aperture image is focused through the objective lens 46 and deflected through the main deflector 48 and the sub-deflector 50, and the substrate 70 placed on the XY stage 62, which continuously moves, is irradiated with the electron beam B at a target position.

The control unit C includes a control calculator 10, storage units 20 and 22, and a control circuit 24. Writing data (layout data) constituted of a plurality of graphic patterns is input from the outside to the storage unit 20 and stored therein.

In the storage unit 22, process parameter historical information, approximate expression information, and global dimensional variation information are stored. Each information is described below. The description about another control circuit that controls the operation of the writing unit W is omitted.

The control calculator 10 includes an input unit 11, a process parameter estimation unit 12, a dimensional variation amount prediction unit 13, a dimensional correction unit 14, a writing data processing part 15, and a determination unit 16.

Each unit of the control calculator 10 may be configured with hardware, such as an electric circuit, or may be configured with software. When it is configured with software, a program that implements at least part of the functions of the control calculator 10 may be stored in a recording medium and read by a computer including an electric circuit to be executed. The recording medium is not limited to what is detachable, such as a magnetic disk or an optical disk, but may be a fixed type recording medium such as a hard disk device or memory.

The electron beam writing apparatus is used in for example, pattern writing of a photomask. In making a photomask, first, a quartz substrate provided with a light shielding film, such as a chromium film, and a resist is prepared and a desired pattern is written on the resist by the electron beam writing apparatus. After the writing, the exposed portions (or unexposed portions) of the resist are dissolved and removed by a development process to form a resist pattern. Subsequently, with the resist pattern as a mask, an etching process is performed by a dry etcher to process the light shielding film. After that, a photomask is made by peeling the resist away. Depending on the kind of the resist, a post exposure bake (PEB) process may be performed before the development process.

In the processes after the pattern writing, such as the development and etching, for each kind of the substrate and resist, the process parameters of the etcher, such as the bias power, pressure, processing time, gas flow rate, gas ratio, gas type, source power, and the like of the etcher are optimized to perform the processes. However, the process parameters gradually vary as time elapses. When the process parameters vary, the dimensions of the light shielding film pattern after the processing vary and the pattern accuracy of the photomask decreases. The parameter setting resolution of the etcher is coarse and it fails to cope with the variation in the process parameters with the lapse of time.

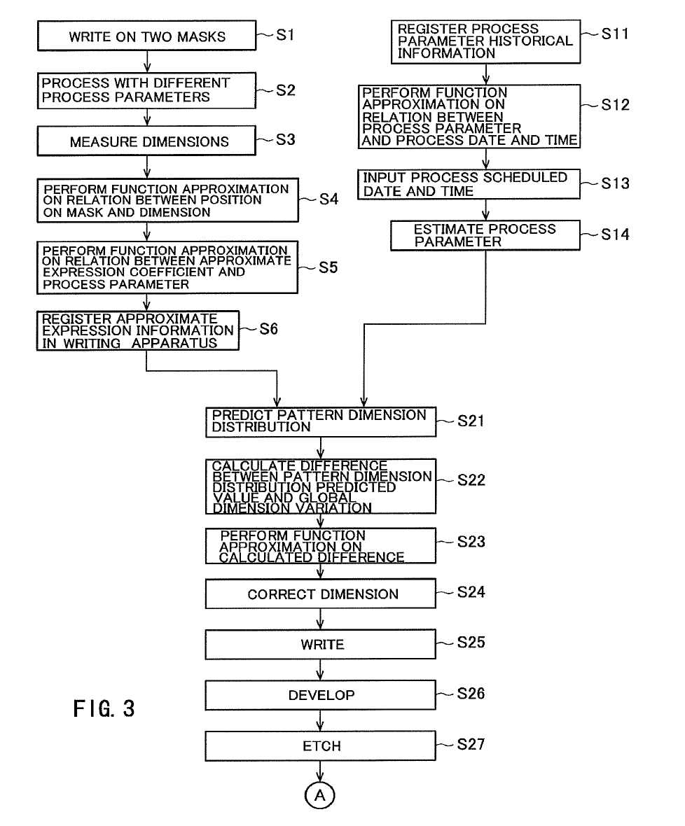

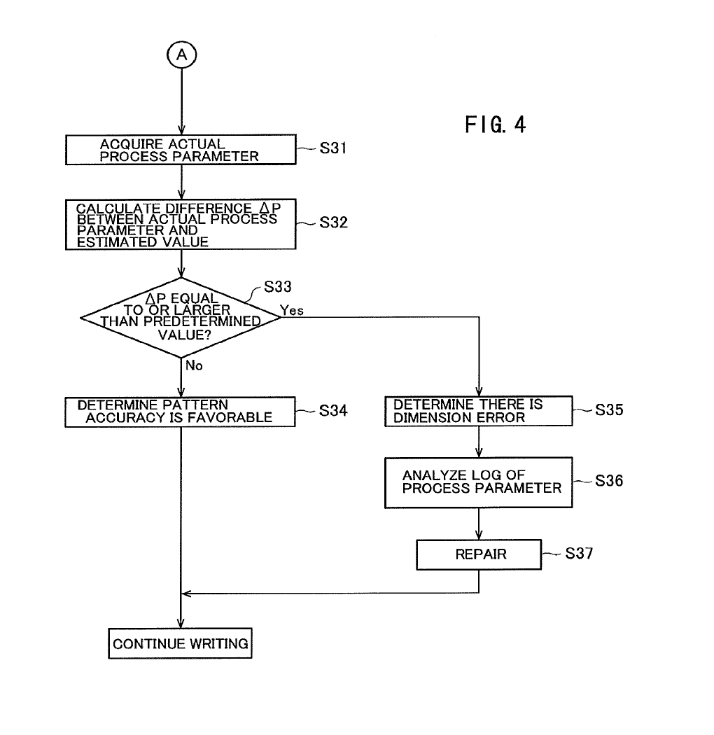

Thus, in the present embodiment, decrease in the pattern accuracy of a photomask that is made is prevented by predicting variation in process parameter and correcting the dimensions of a pattern that is written. A method of making a photomask according to the present embodiment is described using the flow charts illustrated in FIG. 3 and FIG. 4.

Two mask substrates each of which includes a light shielding film and a resist provided over a quartz substrate are prepared and using the writing apparatus illustrated in FIG. 1, the same pattern is written on each of the mask substrates (step S1). The pattern to be written is arbitrary and is, for example, a line and space pattern.

Development and etching processes are performed on the two mask substrates where the pattern is written with different process parameters (step S2). For example, the bias power in the etching process is changed. The etching process is performed with a bias power P1 on the first mask substrate and the etching process is performed with a bias power P2 on the second mask substrate.

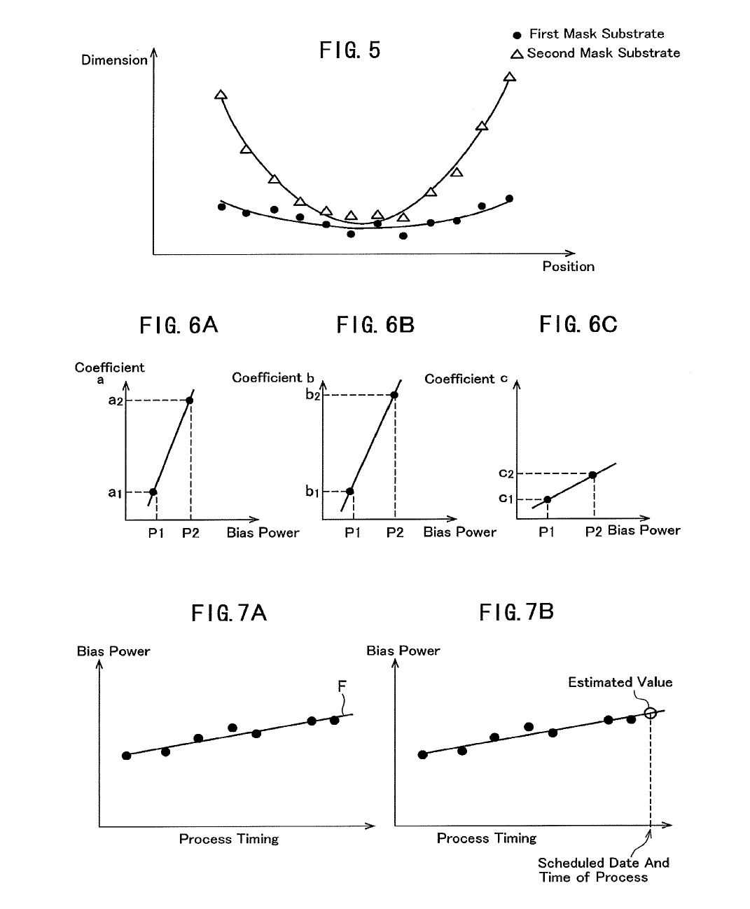

The resist is removed and the dimensions of the light shielding film pattern are measured (step S3). When the process parameter differs, the dimensions vary as well. For example, as illustrated in FIG. 5, the first mask substrate on which the process is performed with the bias power P1 and the second mask substrate on which the process is performed with the bias power P2 are different in pattern dimension distribution.

With regard to each of the first mask substrate and the second mask substrate, the relation between a position on the mask substrate and a pattern dimension is approximated with a function (step S4). When for example, the horizontal axis in FIG. 5 indicates an x coordinate, the pattern dimension is approximated with a quadratic function, such as ax²+bx+c (where a, b, and c represent real numbers). The approximate expression of the pattern dimension distribution of the first mask substrate is a₁x²+b₁x+c₁, and the approximate expression of the pattern dimension distribution of the second mask substrate is a₂x²+b₂x+c₂.

When the coefficients a, b, and c of the approximate expression are each indicated by the vertical axis and a process parameter P is indicated by the horizontal axis, the coefficients a, b, and c are as in FIGS. 6A to 6C, respectively. With regard to each of the coefficients a, b, and c, the relation with the process parameter can be approximated with a linear function, such as dP+e (step S5). While P represents a process parameter, d and e represent real numbers.

For example, approximate expressions, coefficient a=dₐP+eₐ, coefficient b=d_{b}P+e_{b}, and coefficient c=d_{c}P+e_{c}, are determined. Such approximate expressions are for determining the coefficients a, b, and c of the approximate expressions of the pattern dimension distribution on the mask substrate from the value of the process parameter. Coefficients dₐ, eₐ, d_{b}, e_{b}, d_{c}, and e_{c} are registered in the storage unit 22 as the approximate expression information (step S6).

Before or after the registration of the approximate expression information, a history of the process parameter is acquired and registered in the storage unit 22 as the process parameter historical information (step S11). The process parameter estimation unit 12 approximates time-series variation in the process parameter history with a linear function (step S12). For example, the process parameter estimation unit 12 calculates a linear expression F for approximating the process parameter history illustrated in FIG. 7A. FIG. 7A illustrates an example where the vertical axis indicates the bias power.

The input unit 11 accepts input of a process timing (for example, a scheduled date and time of a process) of a substrate that is an object of pattern dimension correction (step S13). The process parameter estimation unit 12 estimates the value of a process parameter at the input process timing using the approximate expression F (step S14). For example, the estimated value of the process parameter illustrated in FIG. 7B is obtained.

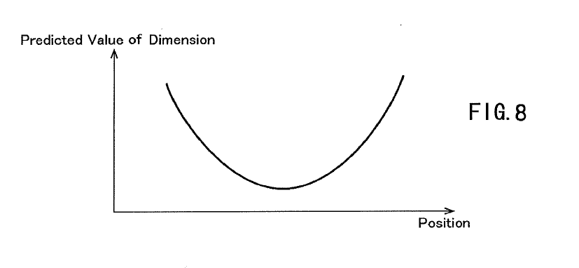

Using the approximate expression information stored in the storage unit 22, the dimensional variation amount prediction unit 13 predicts pattern dimension distribution on the mask substrate in a case where the process is performed with the estimated value of the process parameter calculated in step S14 (step S21). By for example, substituting the estimated value of the process parameter calculated in step S14 into P in the approximate expression, where coefficient a=dₐP+eₐ, coefficient b=d_{b}P+e_{b}, and coefficient c=d_{c}P+e_{c}, the coefficients a, b, and c are determined and the predicted value of the pattern dimension distribution illustrated in FIG. 8 is obtained.

Subsequently, the dimensional variation amount prediction unit 13 calculates a difference between the dimensional variation predicted in step S21 and global dimensional variation, which is determined in advance (step S22). Although on a manufactured mask substrate in general, the difference from a design dimension is small when a position in a chip is close (local), the difference from the design dimension is large in a portion where the position in the chip is far (global). The global dimensional variation is the result of addition of a dimensional error dependent on a pattern and a dimensional error dependent on a position and can be determined by a known technique, such as that described in Japanese Unexamined Patent Application Publication No. 2008-123000. The global dimensional variation determined in advance is registered in the storage unit 22 as the global dimensional variation information.

The dimensional variation amount prediction unit 13 calculates an approximate expression by which the difference determined in step S22 is approximated (step S23).

The dimensional correction unit 14 reads the writing data from the storage unit 21 and according to the dimensional variation amount calculated from the approximate expression determined in step S23, corrects the pattern dimension (design dimension) (step S24).

The writing data processing part 15 performs a data conversion process at a plurality of stages on the writing data after the dimension correction and generates shot data unique to the device. The control circuit 24 computes the deflection amounts at the blanker 36, the shaping deflector 42, the main deflector 48, and the sub-deflector 50 according to the shot data and outputs a control signal to each deflector. Consequently, a predetermined pattern is written at a desired position (step S25).

After the pattern writing, processes such as the development and etching are performed at a predetermined timing (the scheduled date and time input in step S13) to make a photomask (steps S26 and S27).

After the development and etching processes, an actual process parameter is acquired and input to the writing apparatus (step S31 in FIG. 4).

The determination unit 16 calculates a difference ΔP between the process parameter estimated value calculated in step S14 and the actual process parameter input in step S31 (step S32).

When the difference ΔP is smaller than a predetermined value (No in step S33), the determination unit 16 determines that the process parameter is approximately the same as the estimated value and the pattern accuracy of the made photomask is favorable (there is no dimensional variation caused by the processing device) (step S34).

When the difference ΔP is equal to or larger than the predetermined value (Yes in step S33), the determination unit 16 determines that an alienation between the actual process parameter in the development and etching processes is large and the estimated value and a pattern dimension error of the made photomask is large (there is a dimensional variation caused by the processing device) (step S35).

Since it can be deemed in this case that some abnormality is occurring in a processing device, such as the development device or the etcher, the log of the process parameter is analyzed (step S36) and the processing device is repaired (step S37).

Thus, in the present embodiment, variation in process parameter is predicted and the dimensional variation amount accompanied by the variation is corrected to write a pattern. Accordingly, the dimensional accuracy of the pattern formed on a photomask can be increased.

Further, an estimated value of a process parameter and an actual process parameter are compared and an abnormality of a processing device can be detected early from the difference.

The processes of steps S11 to S14 in FIG. 3 and the processes of steps S31 to S36 in FIG. 4 may be performed in the writing apparatus or may be performed in an external device.

The dimension distribution function calculated in step S4 in FIG. 3 may be a function with which the relation between a position in the x direction and a pattern dimension is approximated or may be a function with which the relation between a position in the y direction and a pattern dimension is approximated, or dimension distribution in a mask plane may be calculated by determining both.

Although, in the above-described embodiment, the development and etching processes are performed with different process parameters on two mask substrates where the same pattern is written to determine the approximate expression information, three or more mask substrates where the same pattern is written may be prepared and the processes may be performed with process parameters different from each other on each mask substrate to determine the approximate expression information.

The writing apparatus is not limited to a variable shaping type but may be a multi-beam writing apparatus where irradiation of a plurality of beams is performed at a time.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing apparatus comprising:
an estimator calculating an estimated value of a process parameter of a processing device at a scheduled timing at which a substrate as an object of pattern correction is processed in the processing device from a history of the process parameter of the processing device which performs a process after pattern writing;
a predictor predicting dimension distribution of a pattern formed on the substrate by the processing device performing the process with the estimated value;
a corrector correcting a design dimension based on the predicted dimension distribution; and
a writer irradiating the substrate with a charged particle beam and writing the pattern based on the dimension corrected by the corrector.

2. The apparatus according to claim 1, further comprising a determinator comparing an actual process parameter in the processing device processing the substrate where the pattern is written at the scheduled timing and the estimated value, and determining whether a dimensional variation caused by the processing device is occurred in the pattern on the substrate processed in the processing device based on a result of the comparison.

3. The apparatus according to claim 1, further comprising a storage storing information on a second approximate expression for calculating a coefficient of a first approximate expression from a value of the process parameter, the first approximate expression approximating the dimension distribution of the pattern on the substrate,
wherein the predictor calculates the coefficient of the first approximate expression from the estimated value and the second approximate expression, and predicts the dimension distribution.

4. The apparatus according to claim 1, wherein the process parameter is a bias power, processing time, or pressure of an etcher.

5. A charged particle beam writing method comprising:
calculating an estimated value of a process parameter of a processing device at a scheduled timing at which a substrate as an object of pattern correction is processed in the processing device from a history of the process parameter of the processing device which performs a process after pattern writing;
predicting dimension distribution of a pattern formed on the substrate by the processing device performing the process with the estimated value;
correcting a design dimension based on the predicted dimension distribution; and
irradiating the substrate with a charged particle beam and writing the pattern based on the corrected dimension.

6. The method according to claim 5, further comprising comparing an actual process parameter in the processing device processing the substrate where the pattern is written through the irradiation of the charged particle beam at the scheduled timing and the estimated value, and determining whether a dimensional variation caused by the processing device is occurred in the pattern on the substrate processed in the processing device based on a result of the comparison.

7. The method according to claim 5, wherein
a first approximate expression approximates the dimension distribution of the pattern on the substrate,
a second approximate expression is for calculating a coefficient of the first approximate expression from a value of the process parameter, and
the coefficient of the first approximate expression is calculated by the second approximate expression and the estimated value, and the dimension distribution is predicted.

8. The method according to claim 5, wherein the process parameter is a bias power, processing time, or pressure of an etcher.

9. A pattern forming method comprising:
calculating an estimated value of a process parameter of a processing device at a scheduled timing at which a substrate as an object of pattern correction is processed in the processing device from a history of the process parameter of the processing device which performs a process after pattern writing;
predicting dimension distribution of a pattern formed on the substrate by the processing device performing the process with the estimated value;
correcting a design dimension based on the predicted dimension distribution;
irradiating the substrate with a charged particle beam and writing a pattern based on the corrected dimension; and
performing the process on the substrate where the pattern is written at the scheduled timing using the processing device and forming the pattern on the substrate.

10. The method according to claim 9, further comprising comparing the process parameter of the processing device in processing the substrate at the scheduled timing and the estimated value, and determining whether a dimensional variation caused by the processing device is occurred in the pattern formed on the substrate based on a result of the comparison.

11. The method according to claim 9, wherein
a first approximate expression approximates the dimension distribution of the pattern on the substrate,
a second approximate expression is for calculating a coefficient of the first approximate expression from a value of the process parameter, and
the coefficient of the first approximate expression is calculated by the second approximate expression and the estimated value, and the dimension distribution is predicted.

12. The method according to claim 9, wherein the process parameter is a bias power, processing time, or pressure of an etcher.
